(19) United States
(12) Patent Application Publication
(10) Pub. No.: US 2026/0040673 A1
(43) Pub. Date: Feb. 5, 2026

(54) STACKED TRANSISTOR WITH 2D MATERIAL CHANNELS

(71) Applicant: International Business Machines Corporation, Armonk, NY (US)

(72) Inventors: Darsith Jayachandran, Menands, NY (US); Ruilong Xie, Niskayuna, NY (US); Chen Zhang, Santa Clara, CA (US); HUIMEI ZHOU, Albany, NY (US); Shay Reboh, Guilderland, NY (US); Oleg Gluschenkov, Tannersville, NY (US)

(21) Appl. No.: 18/790,305

(22) Filed: Jul. 31, 2024

(51) Int. Cl. H01L 27/092; H01L 29/06; H01L 29/423; H01L 29/66; H01L 29/775; H01L 29/786

(52) U.S. Cl. CPC H10D 84/856; H10D 30/43; H10D 30/6757; H10D 30/014; H10D 30/6735; H10D 62/121

(57) ABSTRACT

A semiconductor integrated circuit (IC) device includes a bottom source/drain region and a top source/drain region stacked above the bottom source/drain region. The semiconductor IC device further includes a bottom channel that is composed of a first two dimensional (2D) material and is connected to the bottom source/drain region. The semiconductor IC device further includes a top channel that is composed of a second 2D material that is different than the first 2D material and that is connected to the top source/drain region. In examples, the semiconductor IC device further includes a bottom channel interfacial region between the bottom source/drain region and the one or more gates and/or a top channel interfacial region between the top source/drain region and the one or more gates.

### BACKGROUND

The embodiments of the present disclosure relate to fabrication methods and resulting structures for semiconductor integrated circuit (IC) devices.

As demands to reduce the dimensions of transistor devices continue, stacked transistors help achieve a reduced semiconductor IC device footprint while maintaining semiconductor IC device performance. A stacked transistor typically contains at least one transistor stacking over at least another transistor at the same footprint.

Two-dimensional (2D) materials are layered materials consisting of a single or multiple layers of generally planar atoms. The atoms in the layers are held together by saturated covalent bonds. Typically, the thickness of monolayer 2D materials is less than 1 nm. Owing to a typically inert and dangling-bond-free surface, the interface between different 2D material layers is nearly defect-free. Typically, the charge carrier mobility of 2D materials is relatively high.

### SUMMARY

In an embodiment of the disclosure, a semiconductor IC device is presented. The semiconductor IC device includes a bottom source/drain region and a top source/drain region stacked above the bottom source/drain region. The semiconductor IC device further includes a bottom channel composed of a first two dimensional (2D) material connected to the bottom source/drain region. The semiconductor IC device further includes a top channel composed of a second 2D material that is different than the first 2D material and is connected to the top source/drain region.

In an embodiment of a disclosure, another semiconductor IC device is presented. The semiconductor IC device includes a bottom source/drain region and a top source/drain region stacked above the bottom source/drain region. The semiconductor IC device further includes a bottom channel composed of a first two dimensional (2D) material connected to the bottom source/drain region. The semiconductor IC device further includes a top channel composed of a second 2D material that is different than the first 2D material and is connected to the top source/drain region. A vertical dimension of the top channel is greater than a vertical dimension of the bottom channel.

In an embodiment of a disclosure, another semiconductor IC device is presented. The semiconductor IC device includes a bottom source/drain region and a top source/drain region stacked above the bottom source/drain region. The semiconductor IC device further includes a bottom channel composed of a first two dimensional (2D) material connected to the bottom source/drain region. The semiconductor IC device further includes a top channel composed of a second 2D material that is different than the first 2D material and is connected to the top source/drain region. Wherein a vertical dimension of the bottom channel is greater than a vertical dimension of the top channel.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1, which consists of FIG. 1A, FIG. 1B, and FIG. 1C, depicts a cross-section view of a semiconductor IC device that includes a stacked transistor with 2D material channels, according to one or more embodiments of the disclosure.

FIG. 2 depicts a partial top-down view of a semiconductor IC device that includes a stacked transistor with 2D material channels, according to one or more embodiments of the disclosure.

FIG. 3 through FIG. 11 each depict respective fabrication stage cross-section views of an illustrative semiconductor IC device that includes a stacked transistor with 2D material channels, according to one or more embodiments of the disclosure.

FIG. 12 depicts a method of fabricating a semiconductor IC device that includes a stacked transistor with 2D material channels, according to one or more embodiments of the disclosure.

### DETAILED DESCRIPTION

The present disclosure relates to fabrication methods and resulting semiconductor IC devices that includes a stacked transistor with 2D material channels. A stacked transistor typically contains at least one transistor stacking over at least another transistor at the same footprint. For example, the source/drain regions of the top transistor are vertically stacked over the source/drain regions of the bottom transistor. These source/drain regions may connect to a frontside back end of line (BEOL) network or a backside BEOL network. Because of the planar surface of 2D material layers, lattice scattering is suppressed at the atomic thickness, thus enabling high mobility at a sub-1 nm thickness. This quality represents a prominent advantage for continued scaling. The embodiments of the present disclosure recognize the potential benefits of semiconductor IC device fabrication techniques that provide for continued transistor scaling by utilizing 2D material channels within stacked transistors.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped or conductive region in the semiconductor IC device, in which majority carriers are flowing into the channel. A drain is a doped or conductive region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain or consist of multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of +8%, +5%, +2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

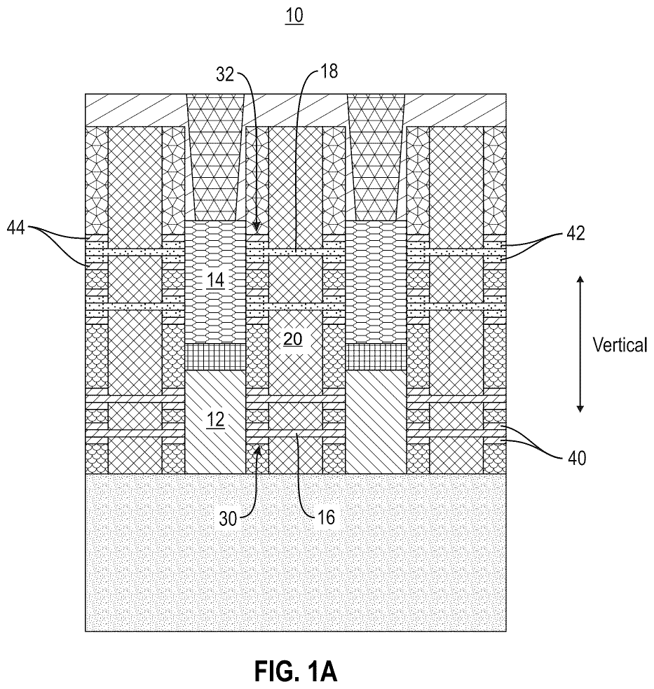

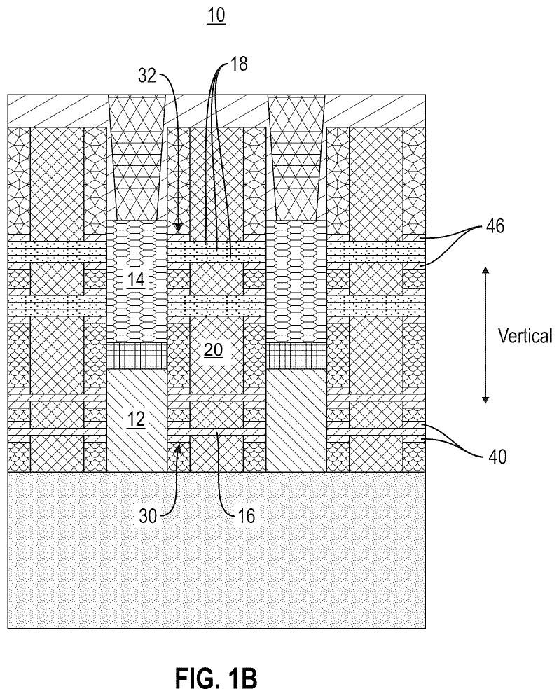

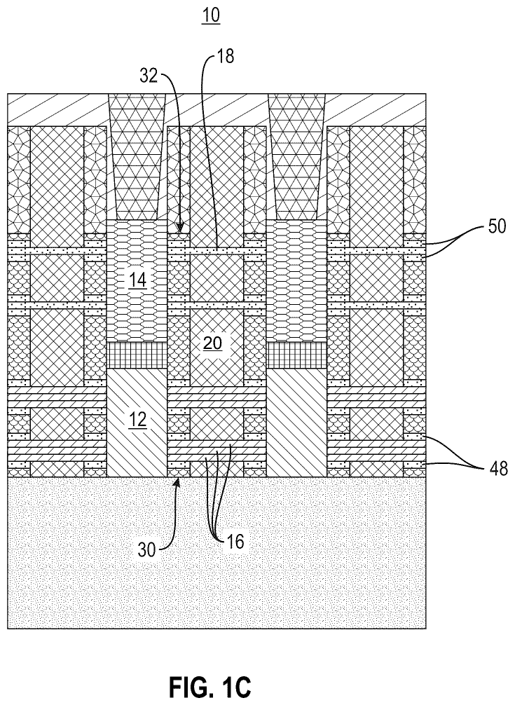

FIG. 1, which consists of FIG. 1A, FIG. 1B, and FIG. 1C, depicts a cross-section view of a semiconductor IC device 10 that includes a stacked transistor with 2D material channels, according to one or more embodiments of the disclosure.

In an illustrative embodiment of the disclosure, as depicted in FIG. 1A, semiconductor IC device 10 includes a bottom source/drain region 12 and a top source/drain region 14 stacked above the bottom source/drain region 12. The semiconductor IC device 10 device further includes a bottom channel 16 composed of a first two dimensional (2D) material connected to the bottom source/drain region 12. The semiconductor IC device 10 device further includes a top channel 18 composed of a second 2D material that is different than the first 2D material and is connected to the top source/drain region 14.

In an example, the semiconductor IC device 10 further includes one or more gates 20 that control charge carrier flow to/from both the bottom source/drain region 12 and the top source/drain region 14 through the bottom channel 16 and the top channel 18, respectively. In this example, the semiconductor IC device 10 may further include a bottom channel interfacial region 30 between the bottom source/drain region 12 and the one or more gates 20. In this example, the semiconductor IC device 10 may further include a top channel interfacial region 32 between the top source/drain region 14 and the one or more gates 20.

In an example, the bottom channel interfacial region 30 comprises a first pair of 2D material layers 40 that encase (e.g., a first 2D material layer is directly above and a second 2D material layer is directly above directly below, or the like) the bottom channel 16. The first pair of 2D material layers 40 are also each composed of the first 2D material.

In an example, the top channel interfacial region 32 comprises a second pair of 2D material layers 42 that encase (e.g., a first 2D material layer is directly above and a second 2D material layer is directly above directly below, or the like) the top channel 18. The second pair of 2D material layers 42 are also each composed of the second 2D material.

In an example, the top channel interfacial region 32 further comprises a third pair of 2D material layers 44 that encase (e.g., a first 2D material layer is directly above and a second 2D material layer is directly above directly below, or the like) the second pair of 2D material layers 42. The third pair of 2D material layers 44 are also each composed of the first 2D material.

In an example, the bottom source/drain region 12 and the top source/drain region 14 are composed of a doped semiconductor material or are composed of the same or different metals. In some examples, the top source/drain region 14 may be oppositely doped relative to the bottom source/drain region 12.

In an example, a vertical dimension of the bottom channel 16 and a vertical dimension of the top channel 18 are substantially the same.

In an example, a vertical dimension of the bottom channel interfacial region 30 is greater than a vertical dimension of the bottom channel 16. Similarly, in an example, a vertical dimension of the top channel interfacial region 32 is greater than a vertical dimension of the top channel 18. Even further, in an example, the vertical dimension of the top channel interfacial region 32 is greater than the vertical dimension of the bottom channel interfacial region 30.

In another illustrative embodiment of the disclosure, as depicted in FIG. 1B, the semiconductor IC device 10 includes the bottom source/drain region 12 and the top source/drain region 14 stacked above the bottom source/drain region 12. The semiconductor IC device 10 further includes the bottom channel 16 that is composed of the first 2D material and is connected to the bottom source/drain region 12. The semiconductor IC device 10 further includes the top channel 18 that is composed of the second 2D material that is different than the first 2D material and that is connected to the top source/drain region 14. The vertical dimension of the top channel 18 is greater than the vertical dimension of the bottom channel 16.

In an example, the semiconductor IC device 10 further includes one or more gates 20 that control charge carrier flow to/from both the bottom source/drain region 12 and the top source/drain region 14 through the bottom channel 16 and the top channel 18, respectively. In this example, the semiconductor IC device 10 further includes the bottom channel interfacial region 30 between the bottom source/drain region 12 and the one or more gates 20 and the top channel interfacial region 32 between the top source/drain region 14 and the one or more gates 20.

In an example, the bottom channel interfacial region 30 includes the first pair of 2D material layers 40 that encase (e.g., a first 2D material layer is directly above and a second 2D material layer is directly above directly below, or the like) the bottom channel 16. In an example, the top channel interfacial region 32 includes a second pair of 2D material layers 46 that encase the top channel 18 (e.g., a first 2D material layer is directly above and a second 2D material layer is directly above directly below, or the like). The second pair of 2D material layers 46 are each composed of the first 2D material.

In an example, the bottom source/drain region 12 and the top source/drain region 14 are composed of a doped semiconductor material, respectively. In an example, the bottom source/drain region 12 and the top source/drain region 14 are composed of a metal, respectively.

In an example, the vertical dimension of the bottom channel interfacial region 30 is greater than a vertical dimension of the bottom channel 16. In an example, a vertical dimension of the top channel interfacial region 32 is greater than a vertical dimension of the top channel 18. In an example, the vertical dimension of the top channel interfacial region 32 is greater than the vertical dimension of the bottom channel interfacial region 30.

In an illustrative embodiment of the disclosure, as depicted in FIG. 1C, semiconductor IC device 10 includes the bottom source/drain region 12 and the top source/drain region 14 stacked above the bottom source/drain region 12. Semiconductor IC device 10 also includes a bottom channel 16 that is composed of the first 2D material and that is connected to the bottom source/drain region 12. The semiconductor IC device 10 also includes the top channel 18 that is composed of the second 2D material that is different than the first 2D material and that is connected to the top source/drain region 14. The vertical dimension of the bottom channel 16 is greater than the vertical dimension of the top channel 18.

In an example, the bottom channel interfacial region 30 includes a first pair of 2D material layers 48 that encase (e.g., a first 2D material layer is directly above and a second 2D material layer is directly above directly below, or the like) the bottom channel 16. The first pair of 2D material layers 48 are each composed of the second 2D material.

In an example, the top channel interfacial region 32 includes a second pair of 2D material layers 50 that encase the top channel 18 (e.g., a first 2D material layer is directly above and a second 2D material layer is directly above directly below, or the like). The second pair of 2D material layers 50 are each composed of the second 2D material.

In an example, the vertical dimension of the top channel interfacial region 32 is greater than a vertical dimension of the top channel 18. In an example, a vertical dimension of the bottom channel interfacial region 30 is greater than a vertical dimension of the bottom channel 16. In an example, the vertical dimension of the bottom channel interfacial region 30 is greater than the vertical dimension of the top channel interfacial region 32.

In another illustrative embodiment of the disclosure, the semiconductor IC device 10 includes the bottom source/drain region 12 and the top source/drain region 14 stacked above the bottom source/drain region 12. In this illustrative embodiment, the bottom source/drain region 12 and the top source/drain region 14 are composed of relatively different metals. The semiconductor IC device 10 further includes the bottom channel 16 that is connected to the bottom source/drain region 12 and the top channel 18 that is connected to the top source/drain region 14. In this example, the bottom channel 16 and the top channel are composed of a substantially same 2D material.

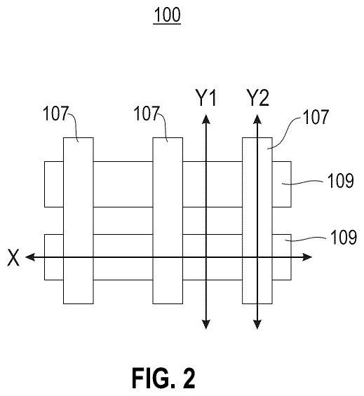

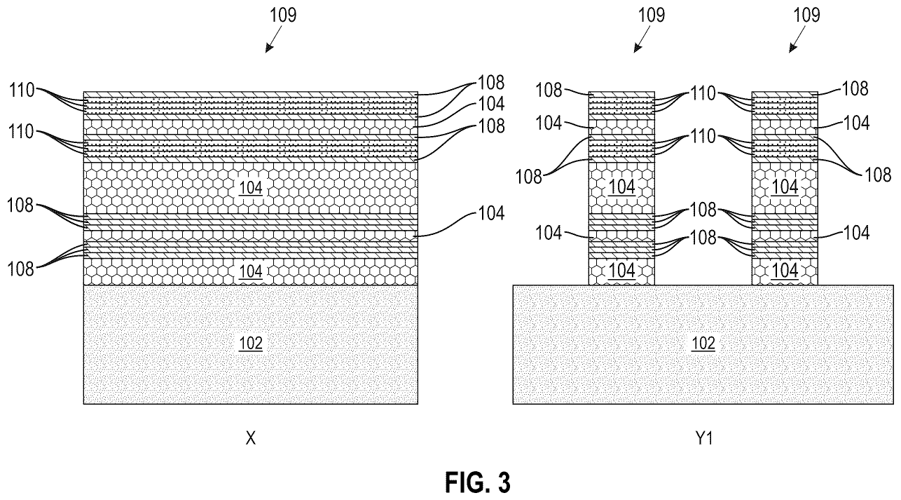

FIG. 2 depicts a partial top down view of a semiconductor IC device 100 that includes a stacked transistor with 2D material channels, according to embodiments of the disclosure. As currently depicted, semiconductor IC device 100 includes nanosheet rows 109 and gate structures 107. FIG. 2 also depicts various cross-sectional planes of the various cross-sectional views of FIG. 3 through FIG. 13. The X cross-sectional plane is through a nanosheet row 109 and across gate structures 107. The Y1 cross-sectional plane is between adjacent gate structures 107 and across nanosheet rows 109. The Y2 cross-sectional plane is through a gate structure 107 and across the nanosheet rows 109.

FIG. 3 depicts fabrication stage cross-section views of an illustrative semiconductor IC device 100. At the present fabrication stage, active 2D material layers 108, active 2D material layers 110, and sacrificial layers 104 are patterned into layered rows 109.

The illustrative semiconductor IC device 100 may be formed by initially providing or forming the substrate structure 102. The substrate structure 102 may be a bulk-semiconductor substrate. In one example, the bulk-semiconductor substrate may be a silicon-containing material. In an implementation, the substrate structure includes an upper substrate, a lower substrate, and an etch stop layer between the upper substrate and the lower substrate. The upper substrate and the lower substrate may be comprised of any suitable semiconductor material(s), and the etch stop layer may be a dielectric material with etch selectivity to one or both upper substrate and/or the lower substrate. In one example, the etch stop layer may be an oxide and the substrate structure may be referred to as a buried oxide (BOX) substrate. In another example, the lower substrate may be composed of Si. The etch stop layer 103 may be composed of Silicon Germanium (SiGe) and may be epitaxially grown from the top surface of lower substrate, and the upper substrate may be composed of Si and may be epitaxially grown from the top surface of etch stop layer.

The illustrative semiconductor IC device 100 may be further formed by forming the respective active 2D material layers 108, active 2D material layers 110, and sacrificial layers 104 over the substrate structure 102.

In certain examples, a bottommost sacrificial layer 104 is initially formed directly on an upper surface of the substrate structure 102. In other examples, certain layer(s) may be formed between the upper surface of the substrate structure 102 and the bottommost sacrificial layer 104. In an example, the bottommost sacrificial layer 104 may be formed by epitaxially growing a SiGe layer with a percentage of Ge, ranging from 20% to 60%, for example. The sacrificial layers 104 may have etch selectivity relative to the active 2D material layers 108 and active 2D material layers 110.

In some embodiments, the active 2D material layers 108 are each composed of a substantially same or similar 2D material. In some embodiments, the active 2D material layers 110 are each composed of a substantially same or similar 2D material that is either the same or different than the active 2D material layers 108. In some embodiments, the active 2D material layers 108 and/or the active 2D material layers 110 may be composed of the same/different 2D material and may further have a p-type dopant therein or a n-type dopant therein.

Exemplary 2D materials may include MoS₂, MoO₃, WS₂, WSe₂, MoTe₂, InSe, MoSe₂, Bi₂O₂Se, h-BN, Graphene, or the like. In an example, the active 2D material layers 108 are composed of one or more 2D materials that are beneficial for p-type transistors (e.g., WSe₂, etc.) and the active 2D material layers 110 are composed of one or more 2D materials that are beneficial for n-type transistors (e.g., MoS₂, etc.). In this example, therefore, a bottom transistor of the stacked transistor may be a p-type transistor (e.g., a pFET) and a top transistor of the stacked transistor may be an n-type transistor (e.g., an nFET).

Generally, the 2D material layers are mono layers consisting of a single layer of atoms, respectively. The 2D material layer may be formed by deposition techniques, such as CVD, ALD, wet/dry transfer techniques, or the like. The 2D material layer may be a crystalline material consisting of a single layer of atoms. A thickness of the 2D material layer may be from, for example, 0.6 nm to 3 nm. Suitable materials include, for example, graphene, TMDs, BN, or the like. For clarity, the plane of the single or each layer of atoms of each active 2D material layers 108 and active 2D material layers 110 may be substantially horizontal or otherwise parallel to the top surface of the substrate structure 102.

In one example the active 2D material layers 108 and the active 2D material layers 110 are 2D material layers as defined in the art. In one example, the active 2D material layers 108 and the active 2D material layers 110 are composed of respective mono layers consisting of a single layer of atoms, respectively (e.g., graphene consists of a single layer of atoms). In an alternative example, one or more of the active 2D material layers 108 and one or more of the active 2D material layers 110 are composed of multiple mono layers each consisting of a single layer of atoms, respectively.

In some examples, the active 2D material layers 108 and the active 2D material layers 110 may be deposited using, for example, chemical vapor deposition (CVD), atmospheric pressure CVD (APCVD), low-pressure CVD (LPCVD) at a sub-atmospheric pressure, plasma enhanced CVD (PECVD), atomic layer CVD (ALCVD), or combinations thereof.

In an implementation, the active 2D material layers 108, active 2D material layers 110, and sacrificial layers 104 may be fabricated by forming each layer until the desired number of layers are formed. The desired number and sequence of layers 108, 110, and 104 can be provided to achieve a particular 2D material channel geometry. In the depicted example, a set of 2D material layers 108 that includes three active 2D material layers 108 may be encased, there above and there below, by a respective sacrificial layer 104. Similarly, a set of active 2D material layers 110 that includes three active 2D material layers 110 may be encased, there above and there below, by an active 2D material layer 108.

Further, in the depicted fabrication stages, active 2D material layers 108, active 2D material layers 110, and sacrificial layers 104 may be patterned into layered rows 109. The one or more layered rows 109 may be formed by lithography and etching techniques.

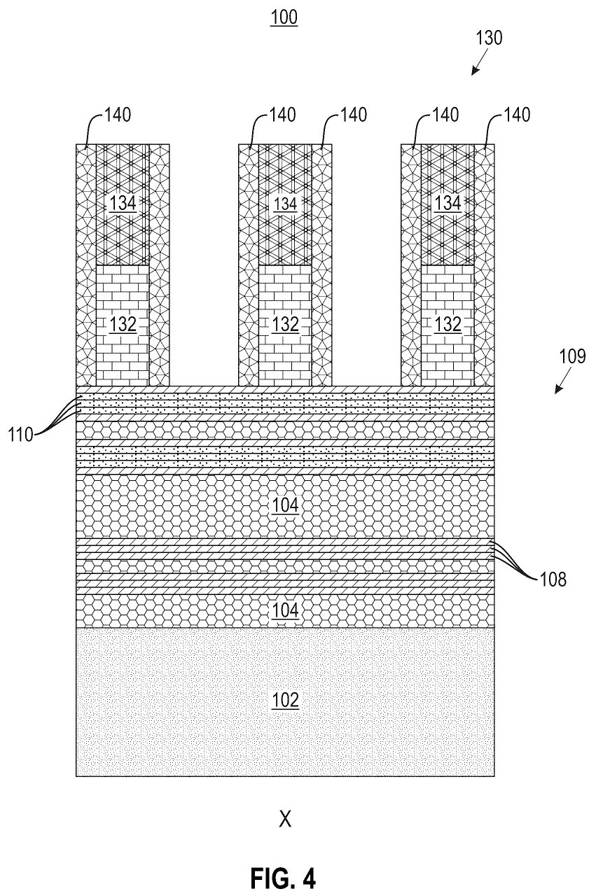

FIG. 4 depicts fabrication stage cross-section views of an illustrative semiconductor IC device 100. At the present fabrication stage, sacrificial gate structures 130 may be formed upon substrate structure 102 and upon and around the layered rows 109 and gate spacers 140 may be formed around the respective sidewalls of the sacrificial gate structures 130.

The sacrificial gate structures may include a sacrificial gate liner (not shown), a sacrificial gate 132, and a sacrificial gate cap 134. The sacrificial gate structures 130 may be formed by initially depositing a sacrificial gate liner layer (e.g., a dielectric, oxide, or the like) upon the substrate structure 102 and upon and around the one or more layered rows 109. The sacrificial gate structures 130 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more layered rows 109. The sacrificial gate structures may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 130 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 132, and the sacrificial gate cap 134, respectively, of each of the one or more sacrificial gate structures 130.

The illustrated semiconductor IC device 100 may be further fabricated by forming gate spacers 140 around the sacrificial gate structures 130. The gate spacer(s) 140 may be formed by a conformal deposition of a dielectric material, such as silicon nitride, SiBCN, SiNC, SiN, SiCO, SiNOC, or a combination thereof, or the like, upon the substrate structure 102, upon around the one or more sacrificial gate structures 130, and upon and around the one or more layered rows 109. Subsequently, undesired portions of dielectric material may be removed while desired portions the dielectric material may be retained and thereby form the gate spacer(s) 140 around the side perimeter of the sacrificial gate structures 130.

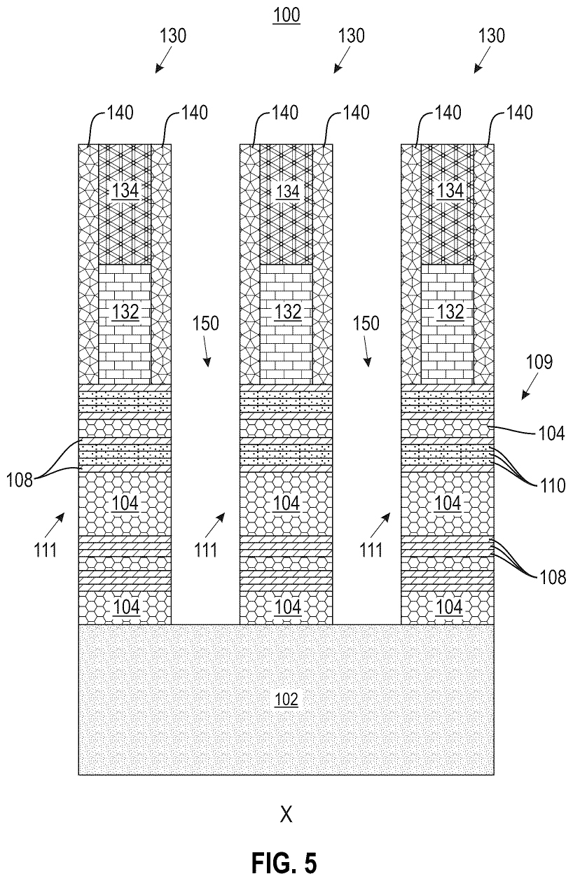

FIG. 5 depicts fabrication stage cross-section views of an illustrative semiconductor IC device 100. At the present fabrication stage, recesses 150 may be formed within the layered rows 109 between gate spacers 140 of neighboring sacrificial gate structures 130.

The recesses 150 may resultantly separate a single layered row 109 into multiple layered stacks 111 each located underneath a portion of respective sacrificial gate structure 130 and associated gate spacers 140. The one or more recesses 150 may be formed between adjacent sacrificial gate structures 130 by removing respective portions of the active 2D material layers 108, active 2D material layers 110, and sacrificial layers 104 that are between gate spacers 140 of adjacent or neighboring sacrificial gate structures 130. The one or more recesses 150 may be formed to a depth to stop at the top surface of the substate structure 102. The undesired portions of the active 2D material layers 108, the active 2D material layers 110, and the sacrificial layers 104 may be removed by etching or other subtractive removal techniques. As the gate spacers 140 and the sacrificial gate structures may be utilized to protect the underlying portions of the active 2D material layers 108, the active 2D material layers 110, and the sacrificial layers 104, respective sidewalls of the layered stacks 111 may be substantially vertical and substantially coplanar with the outer sidewalls of the gate spacers 140, there above.

As used herein, “substantially vertical” sidewalls deviate from a direction perpendicular to a major surface (e.g., top horizontal surface, etc.) of the substrate structure 102 by 5° or less, e.g., 0°, 1°, 2°, 3°, 4°, or 5°, including ranges between any of the foregoing values.

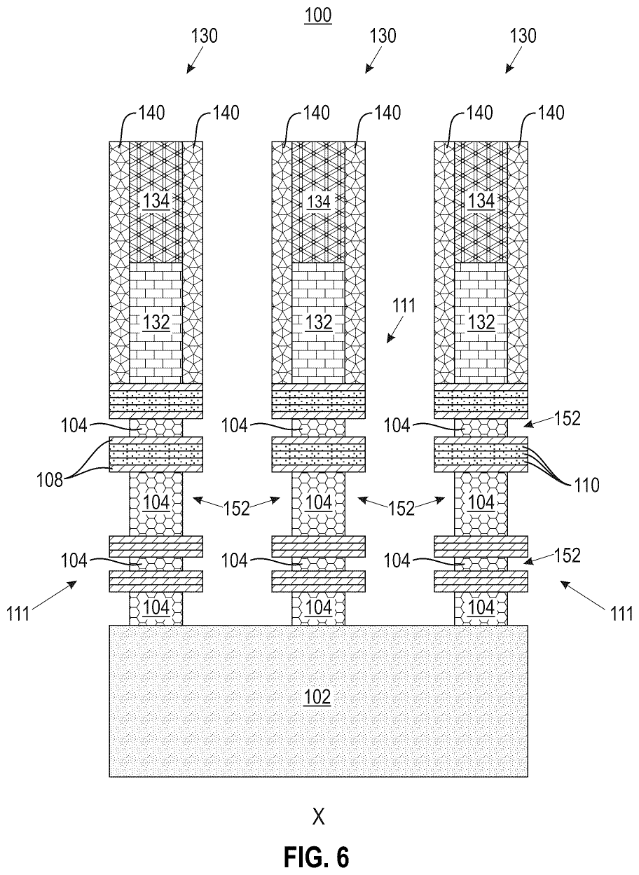

FIG. 6 depicts fabrication stage cross-section views of an illustrative semiconductor IC device 100. At the present fabrication stage, lateral indents 152 by laterally removing respective portions of sacrificial layers 104 within the layered stacks 111.

The lateral indents 152 may be formed by a reactive ion etch (RIE) process, which can remove portions of the sacrificial layers 104. The horizontal depth of the lateral indents 152 may be chosen to set a length for a respective replacement gate structure that is formed in place of a removed sacrificial gate structure 130. When the sacrificial layers 104 are composed of SiGe, the directional RIE can use a boron-based chemistry or a chlorine-based chemistry, for example, which recesses or removes the exposed end portions of sacrificial layers 104 selective to the active 2D material layers 108 and to the active 2D material layers 110. In alternative implementations when sacrificial layers 104 are not SiGe, the directional etch of the sacrificial layers 104 may generally be selective to the active 2D material layers 108, to the active 2D material layers 110, to the gate spacers 140, and/or to the substrate structure 102.

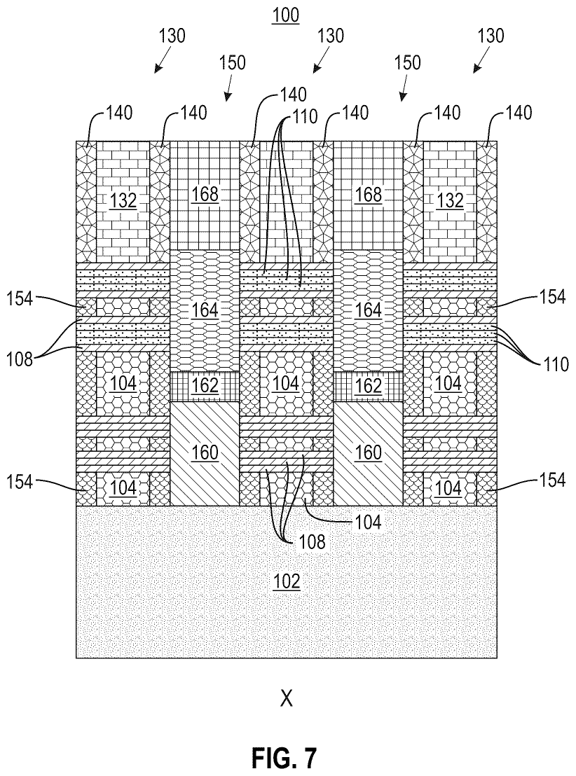

FIG. 7 depicts fabrication stage cross-section views of an illustrative semiconductor IC device 100. At the present fabrication stage, an inner spacer 154 may be formed within the lateral indent 152, a bottom source/drain region 160 may be formed, a middle isolation spacer 162 may be formed, a top source/drain region 164 may be formed, and an interlayer dielectric (ILD) 168 may be formed.

The illustrated semiconductor IC device 100 may be further fabricated by forming a respective inner spacer 154 within each indent 152. The one or more inner spacers 154 can be formed by ALD or CVD or any other suitable deposition technique that deposits a dielectric material within the indent(s) 152, thereby forming the inner spacer(s) 154. In some examples, the inner spacers 154 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacers 154, a directional etch process is performed to create substantially vertical sidewalls of the inner spacers 154 that are coplanar with the substantially vertical sidewalls of the of the gate spacers 140, or the like.

The illustrated semiconductor IC device 100 may be further fabricated by forming bottom S/D regions 160. The bottom S/D regions may be formed by depositing a conductive material, such as a metal, within the recesses 150 and upon the semiconductor structure 102 between adjacent sacrificial gate structures 130. A subsequent etch back may remove undesired conductive material and partially reform recesses 150. A top surface of the bottom S/D regions 160 may be above the top surface of the topmost of the active 2D material layer 108 or the active 2D material layer 110 of the bottom transistor. Each S/D region 160 may form either a source or a drain, respectively, of a respective bottom transistor of the stacked transistor and is connected to respective end surfaces of the active 2D material layer 108 or the active 2D material layer 110 of the bottom transistor. For example, as depicted, the active 2D material layers 108 may serve as the channels between the source and the S/D region 160 of the bottom transistor.

As used herein, a “source/drain” region or “S/D” region can be a source region or a drain region depending on subsequent wiring and application of voltages during operation of the applicable transistor.

The illustrated semiconductor IC device 100 may be further fabricated by forming a middle isolation spacer 162 over the bottom S/D region(s) 160. For example, a blanket middle isolation spacer 162 layer may be deposited over the bottom S/D region(s) 160, over the sacrificial gate structures 130, and over the gate spacers 140, and the like. A subsequent etch back may remove undesired middle isolation spacer 162 over and partially reform recesses 150. The etch back may be controlled to result in a top surface of the middle isolation spacer 162 may be below the bottom surface of the bottom most layer of the active 2D material layer 108 or the active 2D material layer 110 of the top transistor. The blanket middle isolation spacer 162 can be any suitable dielectric material, such as, for example, porous silicates, carbon doped oxides, silicon dioxides, silicon nitrides, silicon oxynitrides, low-K dielectric material, or other dielectric materials.

The illustrated semiconductor IC device 100 may be further fabricated by forming top S/D regions 164. The top S/D regions 164 may be further fabricated by depositing a conductive material, such as a metal, within the recesses 150 and upon the middle isolation spacer 162 between adjacent sacrificial gate structures 130. A subsequent etch back may remove undesired conductive material and partially reform recesses 150. A top surface of the top S/D regions 164 may be above the top surface of the topmost of the active 2D material layer 108 or the active 2D material layer 110 of the top transistor. Each S/D region 164 may form either a source or a drain, respectively, of a respective top transistor of the stacked transistor and is connected to respective end surfaces of the active 2D material layer 108 or the active 2D material layer 110 of the top transistor. For example, the active 2D material layers 110 may serve as the channels between the source and the S/D region 164 of the top transistor.

The illustrated semiconductor IC device 100 may be further fabricated by forming interlayer dielectric (ILD) 168. For example, a blanket ILD 168 may be deposited over the S/D region(s) 164, over the sacrificial gate structures 130, and over the gate spacers 140, and the like.

The ILD 168 can be any suitable dielectric material, such as, for example, porous silicates, carbon doped oxides, silicon dioxides, silicon nitrides, silicon oxynitrides, organic planarization layer (OPL), or other dielectric materials. Subsequently, a planarization process, such as a CMP, may be performed to remove excess ILD 168 material and to remove the sacrificial gate caps 134 of the sacrificial gate structures 130, thereby exposing the sacrificial gate 132 thereunder.

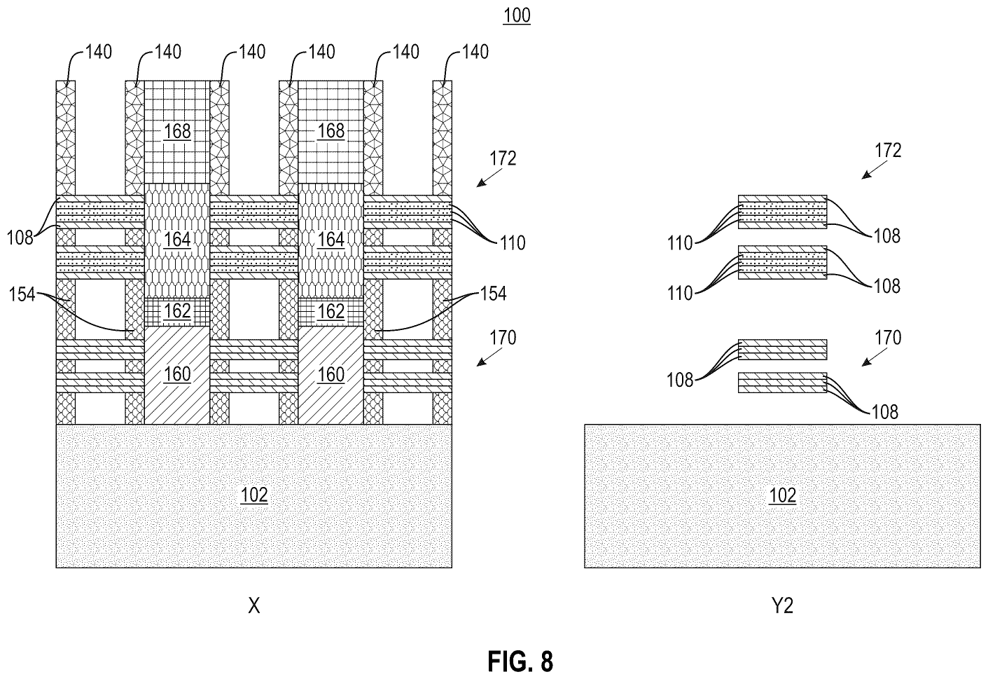

FIG. 8 depicts fabrication stage cross-section views of an illustrative semiconductor IC device 100. At the present fabrication stage, the sacrificial gate structures 130 and the sacrificial layers 104 may be removed.

The illustrated semiconductor IC device 100 may be further fabricated by removing the sacrificial gate structures 130 by initially removing the sacrificial gate 132 and sacrificial layers 104 by a removal technique, such as one or more series of etches. For example, such removal may be accomplished by a wet chemical etching process in which one or more chemical etchants are used to remove the sacrificial gate 132 and sacrificial layers 104 underneath the of the sacrificial gate structures 130 selective to the active 2D material layer 108, to the active 2D material layer 110, to the inner spacers 154, gate spacers 140, substrate structure 102, or the like.

In this manner, one or more bottom channels 170 and one or more top channels 172 may be released by the removal of the sacrificial layers 104 there above and/or below. In the depicted example, at the present fabrication stage, each bottom channel 170 may consist of multiple active 2D material layers 108. In the depicted example, at the present fabrication stage, top bottom channel 170 may consist of multiple active 2D material layers 108 encased by an active 2D material layer 108 there above and there below.

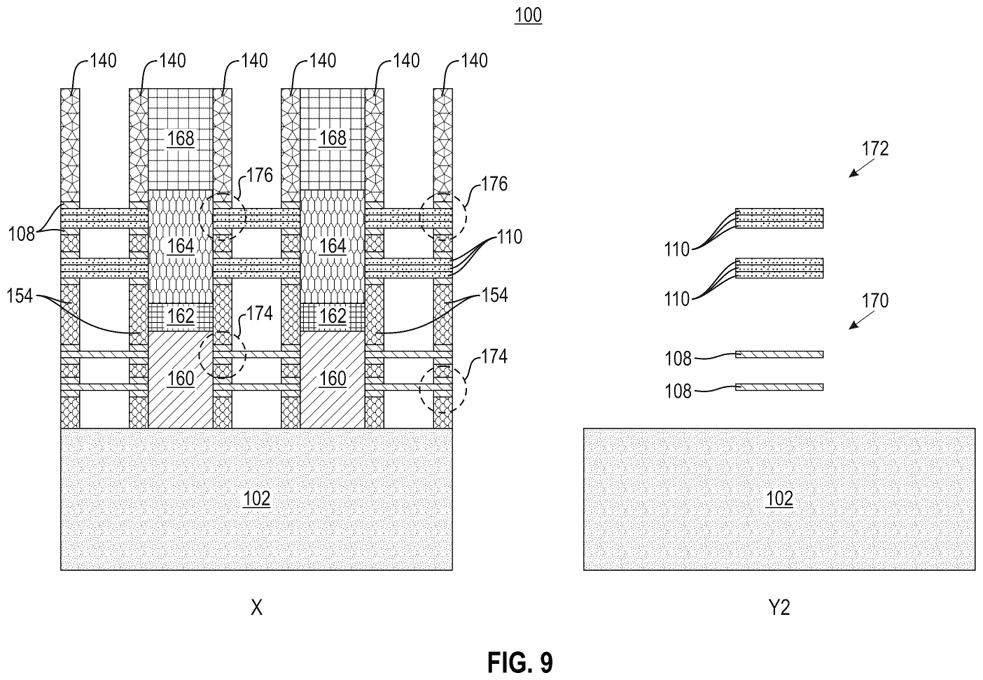

FIG. 9 depicts fabrication stage cross-section views of an illustrative semiconductor IC device 100. At the present fabrication stage, the bottom channel(s) 170 and/or the top channel(s) 172 may be processed. For example, the top and bottom active 2D material layer 108 of the bottom channel(s) 170 may be removed and the top and bottom active 2D material layer 108 of the top channel(s) 172 may be removed.

The bottom channel(s) 170 and/or the top channel(s) 172 may be processed by removing respective one or more active 2D material layers 108 therewithin by a substrative removal technique. For example, an atomic layer etching technique that removes one 2D material layer may remove the top and bottom active 2D material layers 108 from the bottom channel(s) 170 and/or the top channel(s) 172. For example, such removal may be accomplished by a wet chemical etching process in which one or more chemical etchants are used to remove the active 2D material layers 108 selective to the active 2D material layer 110, to the inner spacers 154, gate spacers 140, substrate structure 102, or the like.

The processing of the bottom channel(s) 170 and/or the top channel(s) 172 may form or may begin the formation of one or more bottom channel interfacial region(s) 174 and one or more top channel interfacial region(s) 176. The bottom channel interfacial region(s) 174 and the top channel interfacial region(s) 176 may be located directly under the associated gate spacer 140. For example, sidewall(s) of the gate spacer 140 may be substantially coplanar with respective sidewalls of the bottom channel interfacial region(s) 174 and the top channel interfacial region(s) 176.

The bottom channel interfacial region 174 may include multiple active 2D material layers 108 (e.g., three active 2D material layers 108) while the bottom channel(s) 170 may have relatively fewer active 2D material layers 108 (e.g., one active 2D material layer 108). The top channel interfacial region 176 may include multiple active 2D material layers 110 and multiple active 2D material layers 108 (e.g., three active 2D material layers 110 encased by the active 2D material layer 108 there above and there below) while the top channel(s) 172 may have relatively fewer active 2D material layers (e.g., one active 2D material layer 110, three active 2D material layers 110, etc.).

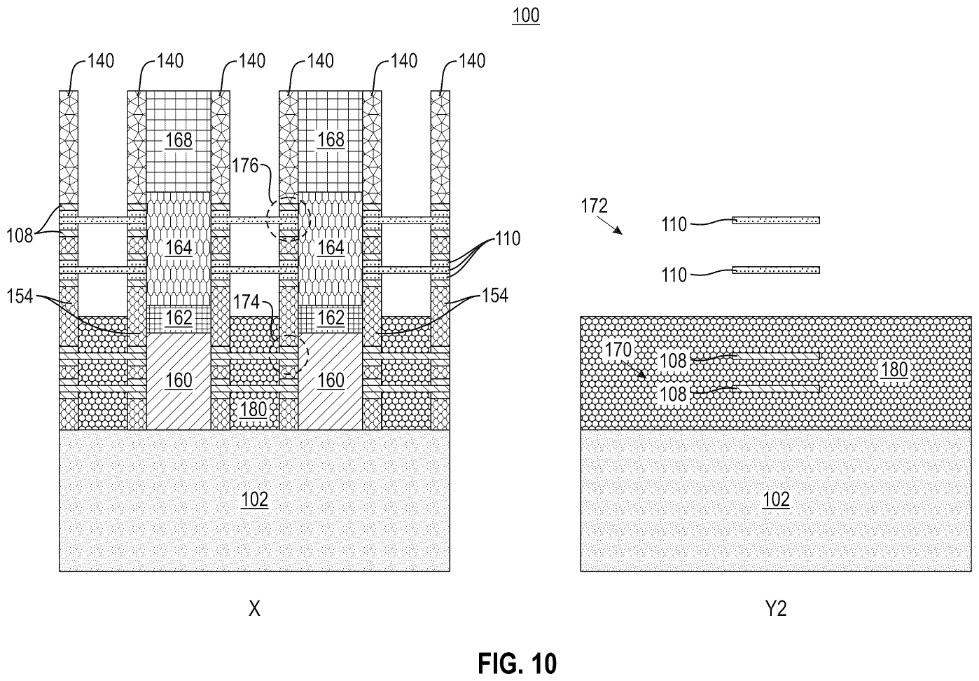

FIG. 10 depicts fabrication stage cross-section views of an illustrative semiconductor IC device 100. At the present fabrication stage, the top channel(s) 172 may be further processed. For example, the top and bottom active 2D material layer 110 of the top channel(s) 172 may be removed.

The top channel(s) 172 may be processed by initially protecting the bottom channels 170 by forming a mask 180, such as an OPL, or other masking materials. The mask 180 may be formed by depositing the masking material as a blanket layer. A subsequent etch back may remove undesired mask 180 material. Subsequently, a top surface of the mask 180 may be above the top channel(s) 170. The top channel(s) 172 may be processed by removing respective one or more active 2D material layers 110 therewithin by a substrative removal technique. For example, the atomic level etch may remove the top and bottom active 2D material layers 110 from the top channel(s) 172. For example, such removal may be accomplished by a wet chemical etching process in which one or more chemical etchants are used to remove the applicable active 2D material layers 110 selective to the mask 180, to the inner spacers 154, gate spacers 140, or the like.

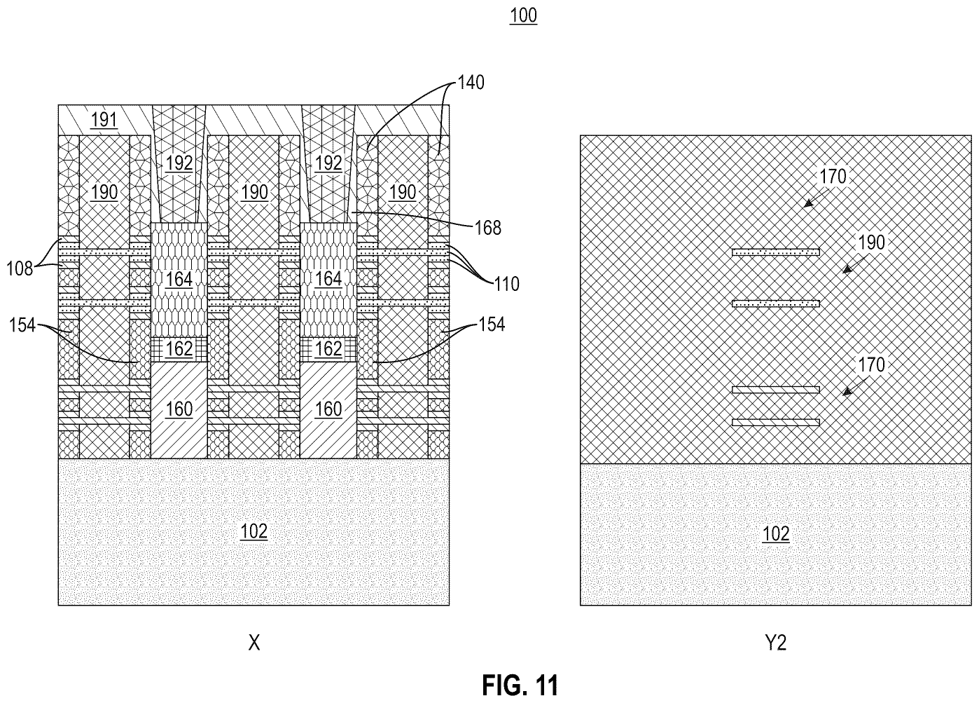

FIG. 11 depicts fabrication stage cross-section views of an illustrative semiconductor IC device 100. At the present fabrication stage, replacement gate structure 190 may be formed in place of the removed sacrificial gate structures 120 (not shown due to removal thereof) around the top channel(s) 172 and around the bottom channel(s) 170.

Replacement gate structure(s) 190 may be formed by initially forming an interfacial layer on the gate spacers 140, around the bottom channel(s) 170, around the top channel(s) 172, and upon on the inner spacers 154, and other surfaces interior to the opening created by the removal of the sacrificial gate structure 130 and the releasing of the bottom channel(s) 170 and the top channel(s) 172.

The replacement gate structure(s) 190 may be further formed by depositing a high-κ (i.e., a dielectric material with a dielectric constant greater than SiO₂). layer to cover the exposed surfaces of the interfacial layer. The high-K layer can include a single layer or multiple layers, such as metal layer, liner layer, wetting layer, and adhesion layer. The replacement gate structure(s) 190 may be further formed by depositing a work function (WF) gate upon the high-K layer. The WF gate can be comprised of a conductor or metal. In general, the WF gate sets the threshold voltage (Vt) of the device. The high-K layer may separate the WF gate from the bottom channel 170 and the top channel 172. Other metals that may be desired to further fine tune the effective work function (EWF) and/or to achieve a desired resistance value associated with current flow through the gate in the direction parallel to the plane of the nanolayer channel.

The replacement gate structure(s) 190 may be further formed by depositing a conductive gate. In an example, when none of the previous replacement gate material(s) are utilized in the replacement gate structures, the conductive gate may be formed upon the same or similar surfaces as those upon which the interfacial layer, described above, may be formed. In other examples, when one or more of the interfacial layer, the high-K layer, the WF gate, or the like, are or are not utilized in the replacement gate structures, the conductive gate may be formed upon the most recent structural formation thereof.

The conductive gate can be comprised of a conductor material and/or metal, such as but not limited to, e.g., tungsten, aluminum, ruthenium, rhodium, cobalt, copper, tantalum, titanium, carbon nanowire materials including graphene, or the like. After the replacement gate structure formation, the top surface of the semiconductor IC device 100 may be planarized by a planarization technique such as a CMP, mechanical grinding process, or the like.

The illustrated semiconductor IC device 100 may be further fabricated by forming a frontside contact ILD 191 (shown as the same material as ILD 191). The frontside contact ILD 191 may be formed upon respective top surfaces of replacement gate structure(s) 190, ILD 168, and gate spacers 140. The frontside contact ILD 191 may be formed by depositing a dielectric material, such as, for example, porous silicates, carbon doped oxides, silicon dioxides, silicon nitrides, silicon oxynitrides, or other dielectric materials.

The illustrated semiconductor IC device 100 may be further fabricated by forming frontside contacts 192 within the frontside contact ILD 191 and the ILD 191. The frontside contacts 192 may be formed by patterning respective frontside contact openings within the ILD layer(s), respectively, from the frontside (i.e., from above the semiconductor IC device 100, as depicted, downward to respective structures thereof). The frontside contacts 192 may be in direct or indirect physical and electrical contact with respective material(s) of one or more regions of the semiconductor IC device 100, such as top S/D regions 164 (as depicted in the cross-section) or such as bottom S/D regions 160 (not depicted in the illustrative cross-section).

The frontside contact(s) 192 may be formed by depositing conductive material such as metal into the respective frontside contact opening(s). In an example, frontside contact(s) 192 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contact(s) 192 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices.

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 100. First, a frontside BEOL network is typically formed on the frontside of the semiconductor device 100. Subsequently, a backside BEOL network may be formed.

The frontside BEOL network may formed over the contact ILD 191 and upon the frontside contacts 192. Respective wires within the frontside BEOL network may be electrically connected to the one or more S/D regions 160, 164, to the one or more replacement gate structure(s) 190, or the like, by a respective frontside contact(s) 192. The frontside BEOL network can include one or more interconnect dielectric material layers (including one of the dielectric materials mentioned above for the frontside ILD 168) and contains metal wires (the metal wires can be composed of any electrically conductive metal or electrically conductive metal alloy) embedded therein. In some embodiments, the frontside metal wires within the frontside BEOL network are composed of Cu. The frontside BEOL network can include “x” numbers of frontside metal levels, wherein “x” is an integer starting from 1. The frontside BEOL network may further contain conductive pads that are connected to one or more of the metal wires and may be used to connect the semiconductor IC device 100 to an external and/or higher-level structure, such as a chip carrier, motherboard, or the like.

For clarity, semiconductor IC device 100 may undergo further fabrication operations. For example, semiconductor IC device 100 may undergo further backside processing, in which backside contacts may be formed, a backside BEOL network may be formed, or the like.

The backside BEOL network, such as a backside power distribution network (BSPDN) may be formed and may include signal wires for signal routing and power wires for providing power potential (e.g., VDD, VSS, etc.). The backside BEOL network may allow for the distribution of power wires and signal wires between both the frontside and backside of the semiconductor IC device. The backside BEOL network may further allow for the full or partial decoupling of signal routing and/or power routing and/or allows for dividing or splitting power wires and/or signal wires between both the frontside and backside of the semiconductor IC device. By incorporating the backside BEOL network, routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network may be electrically connected to the one or more S/D regions (such as bottom S/D regions 160 that are not connected to the top BEOL network) by way of a particular backside contact. The backside BEOL network can include one or more interconnect dielectric material layers and contains backside conductive wires and/or interconnects, such as VIAs, embedded therein. In some embodiments, the backside wires within the backside BEOL network are composed of Cu. The backside BEOL network can include “x” numbers of backside metal levels, wherein “x” is an integer starting from 1. If not included in frontside BEOL network, backside BEOL network may further contain conductive pads that are connected to one or more of the backside metal wires and may be used to connect the semiconductor IC device 100 to the external and/or higher-level structure.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

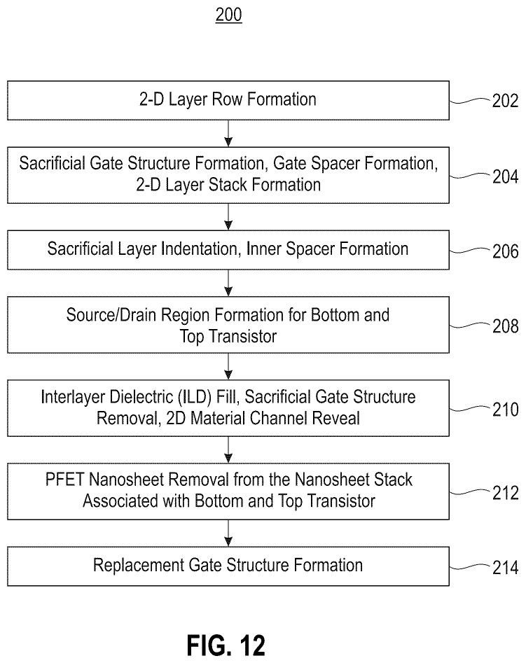

FIG. 12 depicts a flow diagram illustrating a method 200 to fabricate a semiconductor IC device, such as semiconductor IC device 100. The depicted fabrication operations of method 200 are illustratively depicted and described above with reference to one or more of FIG. 3 through FIG. 11 of the drawings, which describe the fabrication of semiconductor IC device 100, though the fabrication operations described in method 200 may be used to fabricate other types of semiconductor IC devices. The method 200 depicted herein is illustrative. There can be many variations to the diagram or operations described therein without departing from the spirit of the embodiments. For instance, the operations can be performed in a differing order, or operations can be added, deleted, or modified.

At block 202, method 200 may begin with patterning active 2D material layers 108, active 2D material layers 110, and sacrificial layers 104 into layered rows 109.

At block 204, method 200 may continue with forming sacrificial gate structures 130, with forming gate spacers 140, and with recessing the layered rows 109 into layered stacks 111.

At block 206, method 200 may continue with indenting the sacrificial layers 104 and forming the inner spacers 154 within the indents.

At block 208, method 200 may continue with forming bottom S/D regions 160 and with forming top S/D regions 164.

At block 210, method 200 may continue with forming ILD 168, with removing the sacrificial gate structures 130, and with revealing the bottom channel 170 and the top channel 172.

At block 212, method 200 may continue with processing the bottom channel 170 and/or the top channel 172.

At block 214, method 200 may continue with forming the replacement gate structure 190 around the bottom channel 170 and around the top channel 172.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a bottom source/drain region and a top source/drain region stacked above the bottom source/drain region;
a bottom channel composed of a first two dimensional (2D) material connected to the bottom source/drain region; and
a top channel composed of a second 2D material that is different than the first 2D material and is connected to the top source/drain region.

2. The semiconductor IC device of claim 1, further comprising:
one or more gates that control charge carrier flow to/from both the bottom source/drain region and the top source/drain region through the bottom channel and the top channel, respectively;
a bottom channel interfacial region between the bottom source/drain region and the one or more gates; and
a top channel interfacial region between the top source/drain region and the one or more gates.

3. The semiconductor IC device of claim 2, wherein the bottom channel interfacial region comprises a first pair of 2D material layers that encase the bottom channel, the first pair of 2D material layers each composed of the first 2D material.

4. The semiconductor IC device of claim 3, wherein the top channel interfacial region comprises a second pair of 2D material layers that encase the top channel, the second pair of 2D material layers each composed of the second 2D material.

5. The semiconductor IC device of claim 4, wherein the top channel interfacial region further comprises a third pair of 2D material layers that encase the second pair of 2D material layers, the third pair of 2D material layers each composed of the first 2D material.

6. The semiconductor IC device of claim 1, wherein the bottom source/drain region and the top source/drain region are composed of one or more metals, respectively.

7. The semiconductor IC device of claim 1, a vertical dimension of the bottom channel and a vertical dimension of the top channel are substantially the same.

8. The semiconductor IC device of claim 2, wherein a vertical dimension of the bottom channel interfacial region is greater than a vertical dimension of the bottom channel.

9. The semiconductor IC device of claim 8, wherein a vertical dimension of the top channel interfacial region is greater than a vertical dimension of the top channel.

10. The semiconductor IC device of claim 9, wherein the vertical dimension of the top channel interfacial region is greater than the vertical dimension of the bottom channel interfacial region.

11. A semiconductor integrated circuit (IC) device comprising:
a bottom source/drain region and a top source/drain region stacked above the bottom source/drain region;
a bottom channel composed of a first two dimensional (2D) material connected to the bottom source/drain region;
a top channel composed of a second 2D material that is different than the first 2D material and is connected to the top source/drain region; and
wherein a vertical dimension of the top channel is greater than a vertical dimension of the bottom channel.

12. The semiconductor IC device of claim 11, further comprising:
one or more gates that control charge carrier flow to/from both the bottom source/drain region and the top source/drain region through the bottom channel and the top channel, respectively;
a bottom channel interfacial region between the bottom source/drain region and the one or more gates; and
a top channel interfacial region between the top source/drain region and the one or more gates.

13. The semiconductor IC device of claim 12, wherein the bottom channel interfacial region comprises a first pair of 2D material layers that encase the bottom channel, the first pair of 2D material layers each composed of the first 2D material.

14. The semiconductor IC device of claim 13, wherein the top channel interfacial region comprises a second pair of 2D material layers that encase the top channel, the second pair of 2D material layers each composed of the first 2D material.

15. The semiconductor IC device of claim 11, wherein a middle isolation spacer is between the bottom source/drain region and the top source/drain region.

16. The semiconductor IC device of claim 11, wherein the bottom source/drain region and the top source/drain region are composed of one or more metals, respectively.

17. The semiconductor IC device of claim 12, wherein a vertical dimension of the bottom channel interfacial region is greater than the vertical dimension of the bottom channel.

18. The semiconductor IC device of claim 17, wherein a vertical dimension of the top channel interfacial region is greater than the vertical dimension of the top channel.

19. The semiconductor IC device of claim 18, wherein the vertical dimension of the top channel interfacial region is greater than the vertical dimension of the bottom channel interfacial region.

20. A semiconductor integrated circuit (IC) device comprising:
a bottom source/drain region composed of a first metal and a top source/drain region composed of a second metal different from the first metal, the top source/drain region stacked above the bottom source/drain region;
a bottom channel composed of a two dimensional (2D) material connected to the bottom source/drain region; and
a top channel composed of the 2D material connected to the top source/drain region.
